(19) United States
(12) Patent Application Publication
(10) Pub. No.: US 2026/0314425 A1
(43) Pub. Date: Oct. 8, 2026

(54) SEMICONDUCTOR PACKAGE INCLUDING SHIELDING LAYER AND BARRIER PATTERN

(71) Applicant: SAMSUNG ELECTRONICS CO., LTD., Suwon-si (KR)

(72) Inventors: Kihong JEONG, Suwon-si (KR); Kiwon BAEK, Suwon-si (KR); Seungmin KIM, Suwon-si (KR); Hongjin KIM, Suwon-si (KR)

(73) Assignee: SAMSUNG ELECTRONICS CO., LTD., Suwon-si (KR)

(21) Appl. No.: 19/353,117

(22) Filed: Oct. 8, 2025

(30) Foreign Application Priority Data
Apr. 2, 2025 (KR) 10-2025-0042746

(51) Int. Cl. H10W 42/20; H10W 70/685; H10W 74/10; H10W 90/00

(52) U.S. Cl. CPC H10W 42/20; H10W 70/685; H10W 74/117; H10W 90/701; H10W 90/724

(57) ABSTRACT

A semiconductor package includes a substrate including first and second surfaces, first pads on the first surface, second pads on the second surface, and a barrier pattern around the second pads along an edge of the second surface; a semiconductor chip on the first surface and including connection pads electrically connected to the first pads; a molding layer on the semiconductor chip; an insulation layer on a portion of each of the second pads and including an open region exposing a portion of the barrier pattern along the edge of the second surface; and a shielding layer on at least a portion of each of the substrate and the molding layer and including an insertion portion extending from the edge of the second surface to the open region, wherein a thickness of the insertion portion decreases toward an outer surface of the insulation layer adjacent to the open region.

### CROSS-REFERENCE TO RELATED APPLICATION(S)

This application claims priority to Korean Patent Application No. 10-2025-0042746, filed on Apr. 2, 2025 in the Korean Intellectual Property Office, the disclosure of which is incorporated by reference herein in its entirety.

### BACKGROUND

The present disclosure relates to a semiconductor package.

In order to protect users of electronic devices or semiconductor chips from electromagnetic interference (EMI), an EMI shielding structure has been utilized in semiconductor packages. In order to improve EMI shielding efficiency and increase productivity, conformal shielding technology of forming shielding layers on surfaces of semiconductor packages has been developed. During the formation of the conformal shielding layer, backspill defects may occur at the edges of package substrates.

### SUMMARY

One or more embodiments of the disclosure provide a semiconductor package which may have improved reliability and productivity.

According to an aspect of the disclosure, a semiconductor package may include: a substrate including a first surface, a second surface opposing the first surface, one or more first pads on the first surface, one or more second pads on the second surface, and a barrier pattern around the one or more second pads along an edge of the second surface; a semiconductor chip on the first surface and including one or more connection pads electrically connected to the one or more first pads; a molding layer on the semiconductor chip on the first surface; an insulation layer on at least a portion of the one or more second pads on the second surface and including an open region exposing at least a portion of the barrier pattern along the edge of the second surface; and a shielding layer on at least a portion of the substrate and the molding layer, and including an insertion portion extending from the edge of the second surface to the open region, wherein a thickness of the insertion portion decreases toward an outer surface of the insulation layer adjacent to the open region.

According to an aspect of the disclosure, a semiconductor package may include: a substrate including a first surface, a second surface opposing the first surface, one or more first pads on the first surface, one or more second pads on the second surface, and a barrier pattern around the one or more second pads; a semiconductor chip on the first surface and including one or more connection pads electrically connected to the one or more first pads; a molding layer on the semiconductor chip on the first surface; an insulation layer on the second surface and including an outer surface spaced apart from the barrier pattern; one or more connection bumps on the one or more second pads; and a shielding layer including a shielding portion on at least a portion of each of the substrate and the molding layer, and an insertion portion extending from one end of the shielding portion toward the outer surface of the insulation layer.

According to an aspect of the disclosure, a semiconductor package may include: a substrate including a ground interconnection, a lower pad electrically connected to the ground interconnection, and a barrier pattern on at least one side of the lower pad; a semiconductor chip on the substrate and electrically connected to the ground interconnection; a molding layer on the semiconductor chip; an insulation layer including an opening exposing the lower pad, and an open region exposing at least a portion of the barrier pattern; a connection bump on the lower pad; and a shielding layer including a shielding portion on at least a portion of each of the substrate and the molding layer, and an insertion portion extending from one end of the shielding portion into to the open region, wherein the barrier pattern is electrically connected to the ground interconnection or the lower pad, and wherein the insertion portion is in contact with the barrier pattern.

### BRIEF DESCRIPTION OF DRAWINGS

The and other aspects, features, and advantages of the disclosure will be more clearly understood from the following detailed description, taken in conjunction with the accompanying drawings, in which:

FIG. 1 is a cross-sectional view of a semiconductor package according to one or more embodiments;

FIG. 2A is a bottom view of a semiconductor package according to one or more embodiments;

FIG. 2B is a bottom view of a semiconductor package according to an exemplary modified example;

FIG. 3 is a partially enlarged view of a semiconductor package according to one or more embodiments;

FIGS. 4A and 4B are partially enlarged views of a semiconductor package according to one or more embodiments;

FIGS. 5A to 5C are partially enlarged views of semiconductor packages according to one or more embodiments;

FIGS. 6A and 6B are partially enlarged views of a semiconductor package according to one or more embodiments;

FIG. 7 is a bottom view of a semiconductor package according to one or more embodiments; and

FIGS. 8A, 8B, 8C, 8D, and 8E are diagrams illustrating a manufacturing process of a semiconductor package according to one or more embodiments.

### DETAILED DESCRIPTION

Hereinafter, embodiments of the present disclosure will be described with reference to the attached drawings. Unless otherwise specified, in this specification, terms, such as ‘upper portion,’ ‘upper surface,’ ‘lower portion,’ ‘lower surface,’ ‘side surface,’ etc. are based on the drawings, and may vary depending on the directions in which components are actually arranged.

In addition, ordinal numbers, such as “first,” “second,” “third,” etc. may be used as labels for specific elements, steps, directions, etc. to distinguish various elements, steps, directions, etc. from each other. Terms that are not described using “first,” “second,” etc. in the specification may still be referred to as “first” or “second” in the claims. Additionally, terms referenced by a particular ordinal number (e.g., “first” in a particular claim) may be described elsewhere with a different ordinal number (e.g., “second” in the specification or other claims).

Furthermore, all of the embodiments of the disclosure described herein are example embodiments, and thus, the disclosure is not limited thereto, and may be realized in various other forms. Each of the embodiments provided in the following description is not excluded from being associated with one or more features of another example or another embodiment also provided herein or not provided herein but consistent with the disclosure.

It will be understood that when an element, component, layer, pattern, structure, region, or so on (hereinafter collectively “element”) of a semiconductor device is referred to as being “over,” “above,” “on,” “below,” “under,” “beneath,” “connected to” or “coupled to” another element of the semiconductor device, it can be directly over, above, on, below, under, beneath, connected or coupled to the other element or an intervening element(s) may be present. In contrast, when an element of a semiconductor device is referred to as being “directly over,” “directly above,” “directly on,” “directly below,” “directly under,” “directly beneath,” “directly connected to” or “directly coupled to” another element of the semiconductor device, there are no intervening elements present. Like numerals refer to like elements throughout this disclosure.

As used herein, the term “and/or” includes any and all combinations of one or more of the associated listed items. As used herein, expressions such as “at least one of,” when preceding a list of elements, modify the entire list of elements and do not modify the individual elements of the list. For example, the expression, “at least one of a, b and c,” and “at least one of a, b, or c” should be understood as including only a, only b, only c, both a and b, both a and c, both b and c, or all of a, b and c.

It will be also understood that, even if a certain step or operation of manufacturing an apparatus or structure is described later than another step or operation, the step or operation may be performed later than the other step or operation unless the other step or operation is described as being performed after the step or operation.

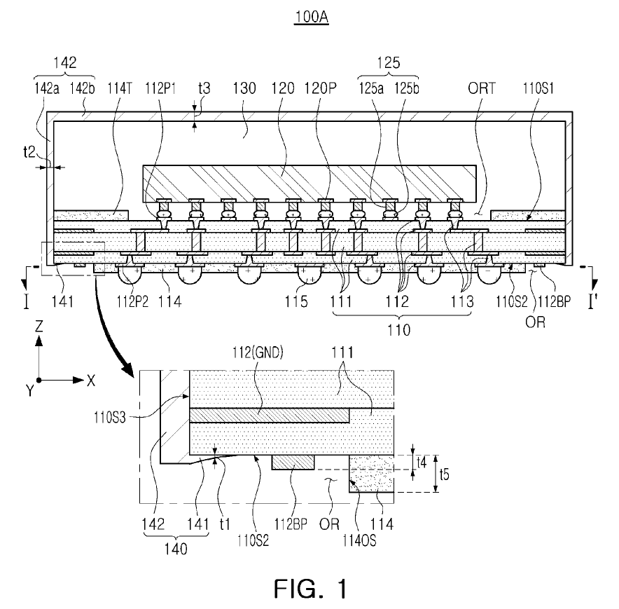

FIG. 1 is a cross-sectional view of a semiconductor package 100A according to one or more embodiments.

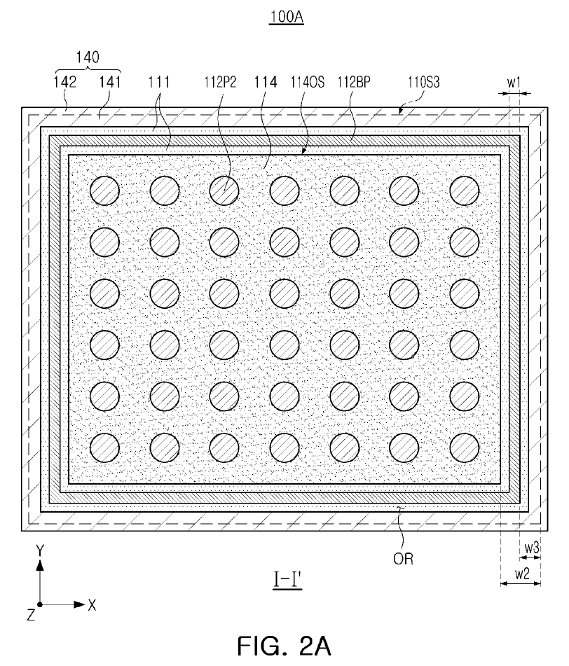

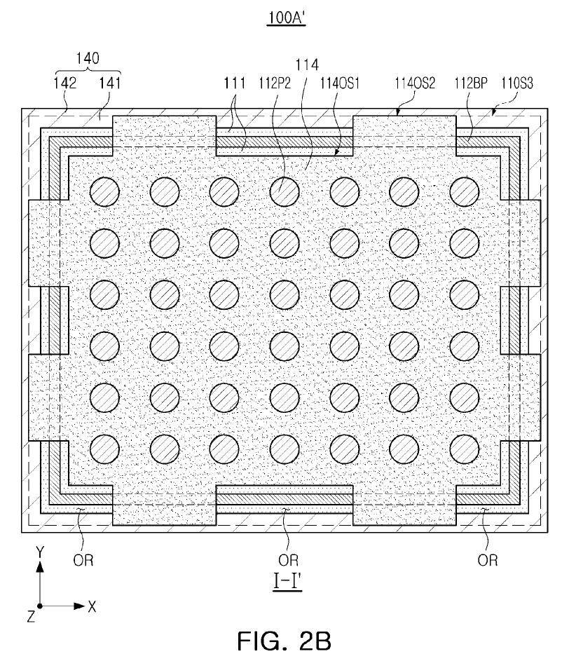

FIG. 2A is a bottom view of a semiconductor package 100A according to one or more embodiments. FIG. 2B is a bottom view of a semiconductor package 100A’ according to a modified example. FIGS. 2A and 2B illustrate cross-sections taken along line I-I’ of FIG. 1.

Referring to FIGS. 1, 2A, and 2B, the semiconductor package 100A according to one or more embodiments may include a substrate 110, a semiconductor chip 120, a molding layer 130, and a shielding layer 140. According to one or more embodiments, a two-stage barrier structure may be formed on a lower surface (hereinafter, a second surface 110S2) of the substrate 110 by a barrier pattern 112BP and an insulation layer 114, thereby preventing short of the shielding layer 140 and an interconnection layer 112 and improving the reliability and productivity of the semiconductor package. The insulation layer 114 may, for example, include a solder resist layer, but is not limited thereto and may include any appropriate insulation material. The barrier pattern 112BP extends along an outer periphery of the substrate 110 to primarily block a portion of the shielding layer 140 from penetrating into the inside of the substrate 110 during a formation process of the shielding layer 140. The insulation layer 114 extends along an inner periphery of the barrier pattern 112BP to secondarily block a portion of the shielding layer 140 from penetrating into the inside of the substrate 110 during the formation process of the shielding layer 140.

The substrate 110 may be a support substrate on which a semiconductor chip 120 is mounted and may be a substrate for a semiconductor package including a printed circuit board (PCB), a ceramic substrate, a glass substrate, a tape interconnection substrate, etc. For example, the substrate 110 may be a double-sided PCB or a multilayer PCB. The substrate 110 may include an insulating layer 111, the interconnection layer 112, and an interconnection via 113.

The insulating layer 111 may include an insulating material electrically and physically protecting the interconnection layer 112, for example, a thermosetting resin, such as an epoxy resin, a thermoplastic resin, such as a polyimide, a prepreg in which these resins are mixed with an inorganic filler or/and glass fiber (glass cloth, glass fabric), a composite resin, such as Ajinomoto build-up film (ABF), frame retardant 4 (FR4), or a photosensitive resin, such as photo-imageable dielectric (PID). The insulating layer 111 may include a plurality of insulating layers 111 that are stacked in a vertical direction (a Z-direction). According to a process, a boundary between the insulating layers 111 may not be apparent. According to one or more embodiments, a smaller or larger number of insulating layers 111 than those illustrated in the drawing may be formed. In some embodiments, the insulating layer 111 may include a core insulating layer to improve the rigidity of the substrate 110. The core insulating layer may be formed using, for example, a copper clad laminate (CCL), an unclad CCL, a glass substrate, or a ceramic substrate.

The interconnection layer 112 provides an electrical connection path within the insulating layer 111 and may redistribute the connection pad 120P of the semiconductor chip 120. The interconnection layer 112 may include a ground interconnection GND that provides a path for applying a ground voltage to the semiconductor chip 120. The ground interconnection GND may provide a ground plane in a plate shape. The interconnection layer 112 may include, for example, copper (Cu), aluminum (Al), silver (Ag), tin (Sn), gold (Au), nickel (Ni), lead (Pb), titanium (Ti), or alloys thereof. The interconnection layer 112 may include a plurality of interconnection layers 112 arranged in the vertical direction (the Z-direction) within the insulating layer 111. The plurality of interconnection layers 112 may be electrically connected to each other through interconnection vias 113. The number of the interconnection layers 112 may be determined according to the number of the insulating layers 111 and may include more or fewer layers than those shown in the drawing.

The interconnection layer 112 may include first pads 112P1 (‘upper pads’) on a first surface 110S1 of the substrate 110 and second pads 112P2 (‘lower pads’) on the second surface 110S2 of the substrate 110. At least a portion of each of the first pads 112P1 and the second pads 112P2 may be connected to the ground interconnection GND of the interconnection layer 112. The first pads 112P1 may be bonding pads on which the semiconductor chip 120 may be mounted. The second pads 112P2 may be arranged on the second surface 110S2, and the outermost second pad 112P2 may be spaced apart from an edge of the second surface 110S2 by a predetermined distance. Here, it may be understood that the edge of the second surface 110S2 coincides with a side surface 110S3 of the substrate 110. The second pads 112P2 may include a ground pad electrically connected to the ground interconnection GND. A barrier pattern 112BP may be disposed on at least one side of the outermost second pad 112P2. The second pads 112P2 may be connected to connection bumps 115. The semiconductor package 100A may be electrically connected to a module substrate, a system board, an interposer, or the like, through the connection bumps 115. The connection bumps 115 may include, for example, tin (Sn) or an alloy including tin (Sn) (e.g., Sn-Ag, Sn-Ag-Cu).

The interconnection via 113 may extend in the vertical direction (the Z-direction) within the insulating layer 111. The interconnection via 113 may be electrically connected to the interconnection layer 112. The interconnection via 113 may include, for example, copper (Cu), aluminum (Al), silver (Ag), tin (Sn), gold (Au), nickel (Ni), lead (Pb), titanium (Ti), or alloys thereof. The interconnection via 113 may have a shape of a filled via in which inside of a via hole may be filled with a metal material or a conformal via in which a metal material may be formed along an inner wall of the via hole.

The insulation layer 114 may be disposed on the second surface 110S2. The insulation layer 114 may cover at least a portion of each of the second pads 112P2 on the second surface 110S2. The insulation layer 114 may include a solder mask defined (SMD)-type or non-solder mask defined (NSMD)-type openings exposing the second pads 112P2. The insulation layer 114 may include an insulating material and may be formed using, for example, a photo solder resist (PSR).

An upper insulation layer 114T may be disposed on the first surface 110S1. The upper insulation layer 114T may include an upper open region ORT exposing the first pads 112P1. In some embodiments, the insulation layer 114T may include a plurality of openings exposing the first pads 112P1, respectively.

In one or more embodiments, the barrier pattern 112BP may extend along an edge 110S3 of the second surface 110S2. The barrier pattern 112BP may have a circular or polygonal ring shape surrounding the second pads 112P2 on the second surface 110S2. The barrier pattern 112BP may include an outer periphery facing the edge 110S3 of the second surface 110S2 and an inner periphery facing the second pads 112P2. The second pads 112P2 may be disposed inside the second surface 110S2 surrounded by the inner periphery of the barrier pattern 112BP. The outer periphery of the barrier pattern 112BP may extend along the edge 110S3 of the second surface 110S2. The inner periphery of the barrier pattern 112BP may face an outer surface 114OS of the insulation layer 114. The barrier pattern 112BP may be formed to surround the outer surface 114OS of the insulation layer 114.

The barrier pattern 112BP may have a line width w1 smaller than a width of the second pads 112P2 in a direction (an X- or Y-direction), parallel to the second surface 110S2. The line width w1 of the barrier pattern 112BP may be about 10 μm or more, for example, in a range of about 10 μm to about 50 μm, about 10 μm to about 40 μm, about 10 μm to about 30 μm, or about 10 μm to about 20 μm. If the line width w1 of the barrier pattern 112BP is less than about 10 μm, a backspill limitation effect of the shielding layer 140 may be reduced.

The barrier pattern 112BP may be spaced apart from the edge 110S3 of the second surface 110S2 by a predetermined distance. A gap w3 between the barrier pattern 112BP and the edge 110S3 of the second surface 110S2 in the direction perpendicular to the outer surface 114OS of the insulation layer 114 (the X- or Y-direction), may be about 10 μm or more.

In one or more embodiments, the insulation layer 114 may include an open region OR exposing at least a portion of the barrier pattern 112BP. The open region OR may be disposed around the outer surface 114OS of the insulation layer 114. The open region OR may be defined as a region not covered with the insulation layer 114 between the edge 110S3 of the second surface 110S2 and the outer surface 114OS of the insulation layer 114. The outer surface 114OS of the insulation layer 114 may be spaced apart from the barrier pattern 112BP in the horizontal direction (the X- or Y-direction). The outer surface 114OS of the insulation layer 114 may be located between the outermost second pad among the second pads 112P2 and the barrier pattern 112BP. On a plane, the second pads 112P2 may be disposed inside the outer surface 114OS of the insulation layer 114, and the barrier pattern 112BP may be disposed outside the outer surface 114OS of the insulation layer 114. A width w2 of the open region OR in the direction perpendicular to the outer surface 114OS of the insulation layer 114 (the X- or Y-direction), may be about 100 μm or more, for example, in the range of about 100 μm to about 120 μm, about 100 μm to about 150 μm, or about 100 μm to about 200 μm.

The insulation layer 114 may have a thickness t5 greater than a thickness t4 of the barrier pattern 112BP in the vertical direction perpendicular to the second surface 110S2 (the Z-direction). The thickness t4 of the barrier pattern 112BP may be substantially equal to a thickness of the second pad 112P2, but is not limited thereto. The thickness t4 of the barrier pattern 112BP may be about 5 μm or more, for example, in a range of about 5 μm to about 20 μm, about 5 μm to about 15 μm, or about 5 μm to about 10 μm. If the thickness t4 of the barrier pattern 112BP is less than about 5 μm, the backspill limitation effect of the shielding layer 140 may be reduced.

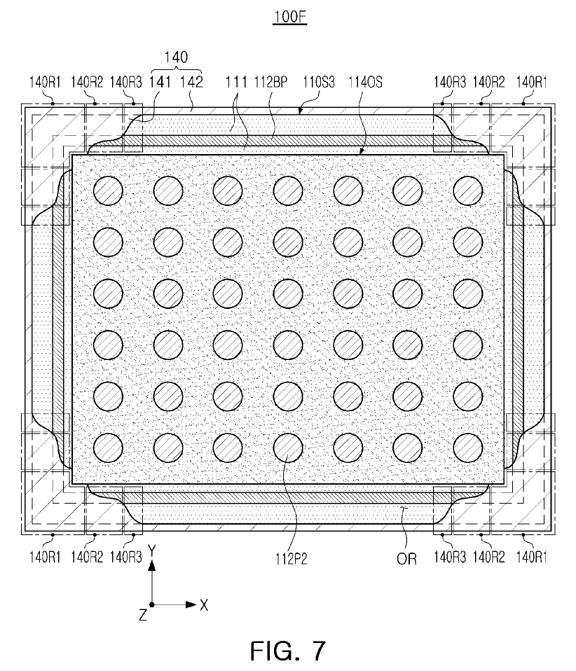

As illustrated in FIG. 2A, in the semiconductor package 100A of one or more embodiments, the open region OR may expose the entire barrier pattern 112BP along the edge 110S3 of the second surface 110S2. The open region OR may extend continuously along the outer periphery of the insulation layer 114. The open region OR may be at least partially covered with an insertion portion 141 of the shielding layer 140. In some embodiments, the open region OR may include a region that is not covered with the insertion portion 141 (see FIG. 7).

As illustrated in FIG. 2B, in the semiconductor package 100A’ of a modified example, the open region OR may partially expose the barrier pattern 112BP along the edge 110S3 of the second surface 110S2. In the modified example, the open region OR may include a plurality of open regions OR spaced apart from each other along the edge 110S3 of the second surface 110S2. The insulation layer 114 may include first outer surfaces 114OS1 adjacent to an inner end of each of the plurality of open regions OR and second outer surfaces 114OS2 adjacent to the edge 110S3 of the second surface. The insertion portion 141 of the shielding layer 140 may extend from the edge 110S3 of the second surface toward the first outer surfaces 114OS1.

The semiconductor chip 120 may be disposed on the first surface 110S1 of the substrate 110 and may include connection pads 120P electrically connected to the first pads 112P1. The connection pads 120P may include at least one metal among copper (Cu), aluminum (Al), nickel (Ni), silver (Ag), gold (Au), platinum (Pt), tin (Sn), lead (Pb), titanium (Ti), chromium (Cr), palladium (Pd), indium (In), and zinc (Zn), or an alloy of two or more metals thereof. The connection pads 120P may be electrically connected to the first pads 112P1 through bump structures 125. The bump structures 125 may include a pillar 125a and a solder ball 125b. The pillar 125a may include at least one metal among copper (Cu), aluminum (Al), nickel (Ni), silver (Ag), gold (Au), platinum (Pt), tin (Sn), lead (Pb), titanium (Ti), chromium (Cr), palladium (Pd), indium (In), and zinc (Zn), or an alloy of two or more metals thereof. The solder ball 125b may be formed of tin (Sn) or an alloy including tin (Sn), for example, an alloy including at least two or more of tin (Sn), lead (Pb), silver (Ag), copper (Cu), and bismuth (Bi). According to one or more embodiments, the bump structure 125 may include only one of the pillar 125a or the solder ball 125b. In one or more embodiments, the connection pads 120P may be connected to the first pads 112P1 via bonding wires.

The semiconductor chip 120 may include a semiconductor wafer formed of a semiconductor element, such as silicon or germanium, or a compound semiconductor, such as silicon carbide (SiC), gallium arsenide (GaAs), indium arsenide (InAs), and indium phosphide (InP) and an integrated circuit (IC). The semiconductor chip 120 may be a bare semiconductor chip, but may be not limited thereto, and may also be a packaged-type semiconductor chip. The semiconductor chip 120 may include a logic chip, such as a central processor (CPU), a graphics processor (GPU), a field programmable gate array (FPGA), an application processor (AP), a digital signal processor, an encryption processor, a microprocessor, a microcontroller, an analog-to-digital converter, an application-specific IC (ASIC) or a memory chip including a volatile memory, such as a dynamic RAM (DRAM) or a static RAM (SRAM) or a nonvolatile memory, such as a phase change RAM (PRAM), a magnetic RAM (MRAM), a resistive RAM (RRAM), or a flash memory.

The molding layer 130 may encapsulate the semiconductor chip 120 on the first surface 110S1 of the substrate 110. The molding layer 130 may include an insulating resin, such as an epoxy molding compound (EMC), for example. The molding layer 130 may fill a lower portion of the semiconductor chip 120 in a molded underfill (MUF) manner. In some embodiments, a capillary underfill (CUF)-type underfill may be formed in the lower portion of the semiconductor chip 120.

The shielding layer 140 may cover at least a portion of each of the substrate 110 and the molding layer 130. The shielding layer 140 may include a material for EMI shielding, for example, iron (Fe), nickel (Ni), gold (Au), silver (Ag), copper (Cu), and alloys thereof. The shielding layer 140 may be connected to the ground interconnection GND on at least one side of the substrate 110. The shielding layer 140 may include a multilayer thin film including two or more layers. In one or more embodiments, the shielding layer 140 may include the insertion portion 141 and a shielding portion 142.

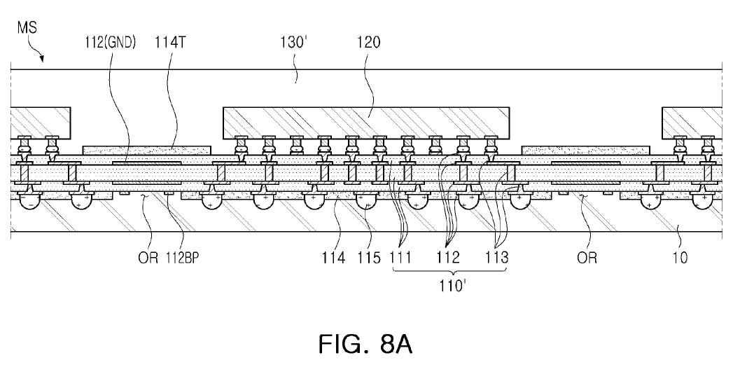

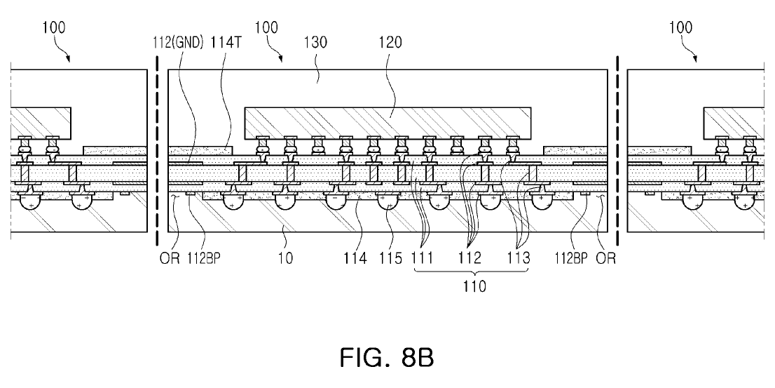

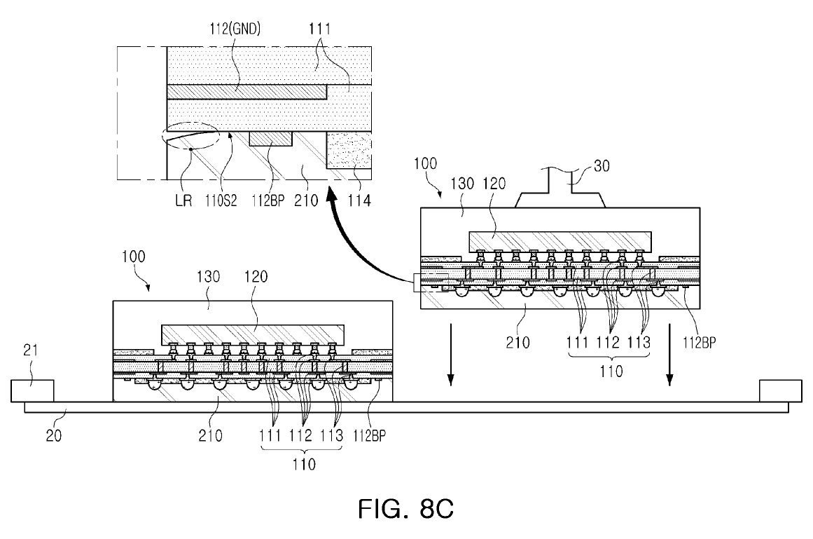

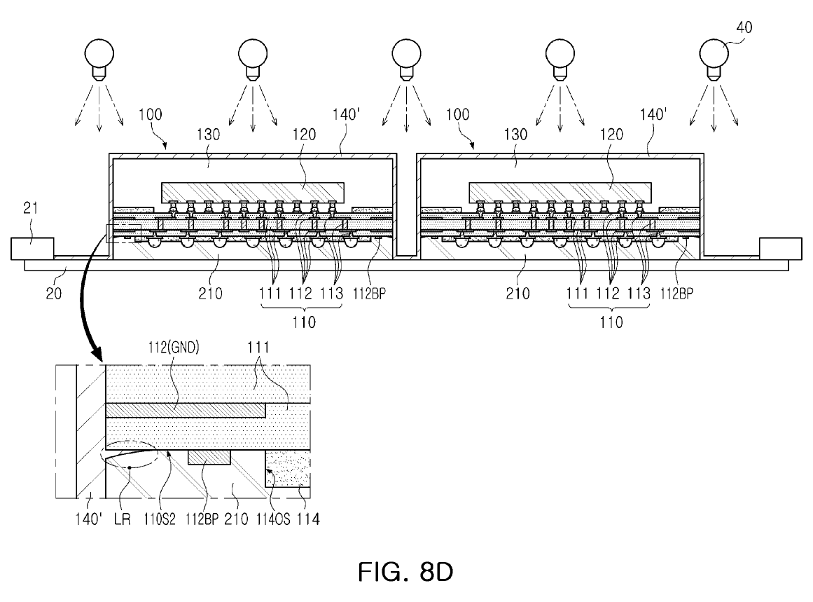

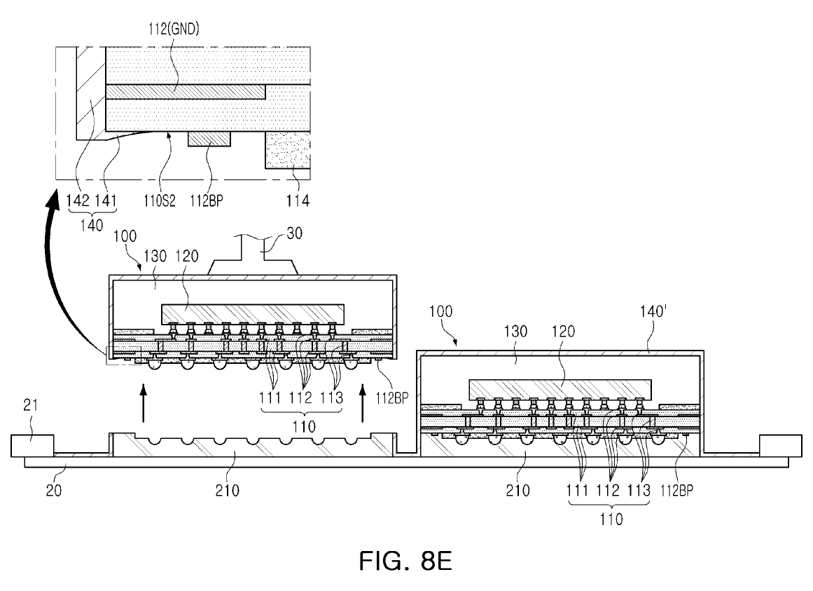

The insertion portion 141 may cover the second surface 110S2 of the substrate 110. The insertion portion 141 may extend from the edge 110S3 of the second surface 110S2 toward the inside of the open region OR. Here, the ‘inside’ of the open region OR may be defined as a portion adjacent to the outer surface 114OS of the insulation layer 114. In other words, the insertion portion 141 may extend from one end of the shielding portion 142 toward the outer surface 114OS of the insulation layer 114. The insertion portion 141 may be formed of a shielding material penetrating into a lifted region (refer to ‘LR’ of FIG. 8C) of an adhesive layer during the formation process of the shielding layer 140. A thickness t1 of the insertion portion 141 may decrease toward the inside of the open region OR. That is, the thickness t1 of the insertion portion 141 may decrease as the insertion portion 141 extends toward the outer surface 114OS of the insulation layer 114 adjacent the open region OR.

The shielding portion 142 may be integrally connected to the insertion portion 141. The shielding portion 142 may cover at least a portion of each of the substrate 110 and the molding layer 130. The shielding portion 142 may include a first shielding portion 142a covering the side surface of the substrate 110 and the side surface of the molding layer 130 and a second shielding portion 142b covering the upper surface of the molding layer 130. A thickness t2 of the first shielding portion 142a and a thickness t3 of the second shielding portion 142b may be greater than the thickness t1 of the insertion portion 141. In one or more embodiments, the shielding layer 140 may be connected to the ground interconnection GND of the substrate 110 through the first shielding portion 142a.

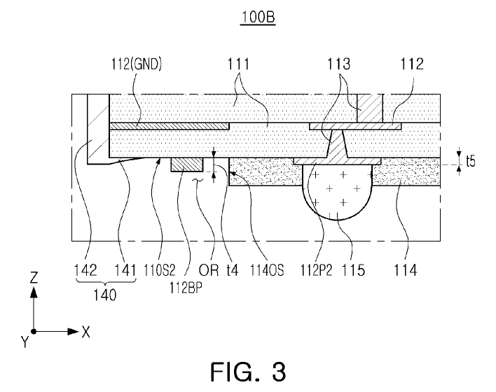

FIG. 3 is a partially enlarged view of a semiconductor package 100B according to one or more embodiments. FIG. 3 illustrates a portion of the semiconductor package 100B of the embodiment corresponding to the enlarged portion illustrated in FIG. 1.

Referring to FIG. 3, the semiconductor package 100B of the embodiment may have the same or similar features as those described above with reference to FIGS. 1, 2A, and 2B, except for the thickness t4 of the barrier pattern 112BP. The barrier pattern 112BP may have the thickness t4 greater than the thickness t5 of the second pads 112P2 in the vertical direction (the Z-direction) perpendicular to the second surface 112S2. The thickness t4 of the barrier pattern 112BP may be smaller than the thickness of the insulation layer 114. A lower surface of the barrier pattern 112BP may be located between a lower surface of the second pads 112P2 and a lower surface of the insulation layer 114. The thickness t4 of the barrier pattern 112BP may be greater than the thickness of the insertion portion 141. By adjusting the thickness t4 of the barrier pattern 112BP during a plating process, lifting of the adhesive layer (see ‘LR’ in FIG. 8C) during the formation of the shielding layer 140 may be suppressed.

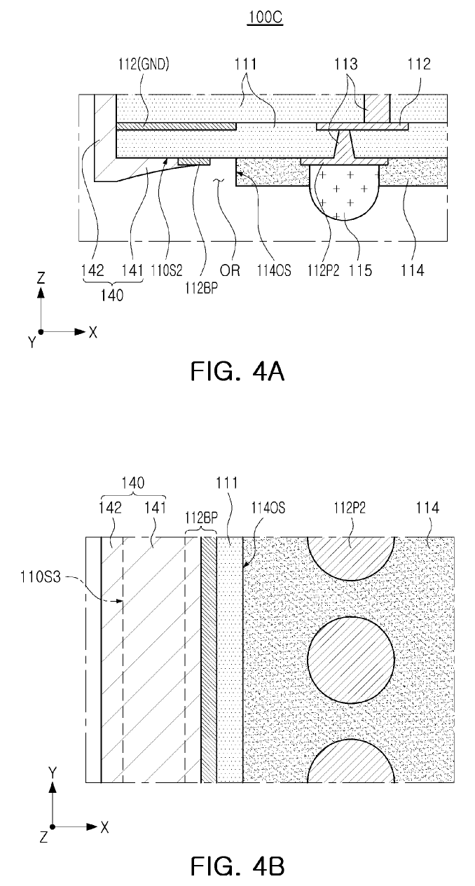

FIGS. 4A and 4B are partially enlarged views of a semiconductor package 100C according to one or more embodiments. FIG. 4A illustrates a portion of the semiconductor package 100C of the embodiment corresponding to the enlarged portion illustrated in FIG. 1. FIG. 4B illustrates a bottom surface of the portion illustrated in FIG. 4A.

Referring to FIGS. 4A and 4B, the semiconductor package 100C of the embodiment may have the same or similar features as those described above with reference to FIGS. 1, 2A, 2B, and 3, except that the barrier pattern 112BP may be connected to the ground interconnection GND. The barrier pattern 112BP may be electrically connected to the ground interconnection GND of the substrate 110 through the shielding layer 140, and EMI shielding characteristics may be improved. The insertion portion 141 of the shielding layer 140 may extend into the open region OR and contact at least a portion of the barrier pattern 112BP. The thickness of the insertion portion 141 in the vertical direction (the Z-direction) may decrease toward the barrier pattern 112BP. According to one or more embodiments, unlike that illustrated in FIG. 4B, an overlapping region of the insertion portion 141 and the barrier pattern 112BP may not be uniform (see FIG. 7).

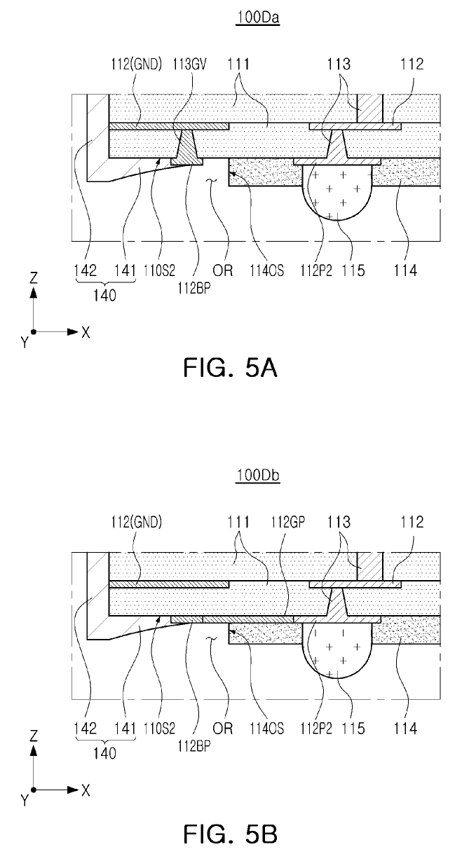

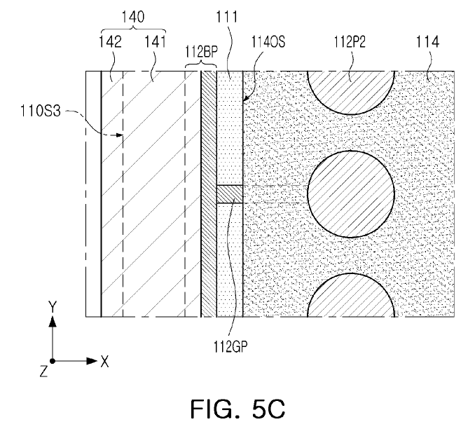

FIGS. 5A to 5C are partially enlarged views of semiconductor packages 100Da and 100Db according to embodiments. FIGS. 5A and 5B illustrate portions of the semiconductor packages 100Da and 100Db of the embodiment corresponding to the portion illustrated in an enlarged manner in FIG. 1, respectively. FIG. 5C illustrates a bottom surface of the portion illustrated in FIG. 5B.

Referring to FIG. 5A, the semiconductor package 100Da of the embodiment may have the same or similar features as those described above with reference to FIGS. 1, 2A, 2B, 3, 4A, and 4B, except that the barrier pattern 112BP may be connected to the ground interconnection GND through a ground via 113GV. The substrate 110 may further include the ground via 113GV connecting the barrier pattern 112BP to the ground interconnection GND. The ground via 113GV may penetrate through the insulating layer 111 and electrically connect the barrier pattern 112BP to the ground interconnection GND. The ground via 113GV may have a filled via or a conformal via form.

Referring to FIGS. 5B and 5C, the semiconductor package 100Db of the embodiment may have the same or similar features as those described above with reference to FIGS. 1, 2A, 2B, 3, 4A, and 4B, except that the barrier pattern 112BP may be connected to the second pad 112P2 via the ground pattern 112GP. The substrate 110 may further include a ground pattern 112GP connecting the barrier pattern 112BP to at least a portion of the second pad 112P2. The at least a portion of the second pad 112P2 may be a ground pad electrically connected to the ground interconnection GND. The ground pattern 112GP may extend in the horizontal direction (the X- or Y-direction) between the barrier pattern 112BP and the ground pad. According to one or more embodiments, unlike that illustrated in FIG. 5C, the ground pattern 112GP may extend in two or more horizontal directions (the X- or Y-direction). In this manner, when the barrier pattern 112BP may be directly connected to the ground pad, the ground interconnection GND exposed to the side surface 110S3 of the substrate 110 for grounding the shielding layer 140 may be omitted.

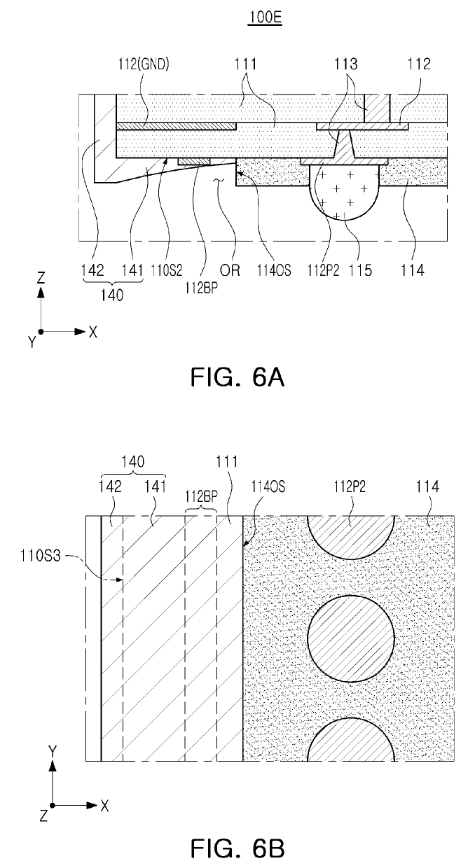

FIGS. 6A and 6B are partially enlarged views of a semiconductor package 100E according to one or more embodiments. FIG. 6A illustrates a portion of the semiconductor package 100E of one or more embodiments corresponding to a portion enlarged in FIG. 1. FIG. 6B illustrates a bottom surface of the portion illustrated in FIG. 6A.

Referring to FIGS. 6A and 6B, the semiconductor package 100E of one or more embodiments may have the same or similar features as those described above with reference to FIGS. 1, 2A, 2B, 3, 4A, 4B, 5A, 5B, and 5C, except that the insertion portion 141 extends to the outer surface 114OS of the insulation layer 114. The insertion portion 141 of the shielding layer 140 may extend into the open region OR to contact the barrier pattern 112BP and the outer surface 114OS of the insulation layer 114. The thickness of the insertion portion 141 in the vertical direction (the Z-direction) may decrease toward the outer surface 114OS of the insulation layer 114. According to one or more embodiments, unlike that illustrated in FIG. 6B, the contact between the insertion portion 141 and the outer surface 114OS of the insulation layer 114 may not be uniform (see FIG. 7).

FIG. 7 is a bottom view of a semiconductor package 100F according to one or more embodiments. FIG. 7 may be a bottom view of the semiconductor package 100F according to the embodiment corresponding to the portion illustrated in FIG. 2A.

Referring to FIG. 7, the semiconductor package 100F of the embodiment may have the same or similar features as those described above with reference to FIGS. 1, 2A, 2B, 3, 4A, 4B, 5A, 5B, 5C, 6A, and 6B, except that a region in which the insertion portion 141 of the shielding layer 140 includes a plurality of regions 140R1,140R2, and 140R3 different from each other. The shielding layer 140 may include at least one of the first region 140R1, the second region 140R2, or the third region 140R3. The first region 140R1, the second region 140R2, or the third region 140R3 may be formed depending on the degree of lifting of the adhesive layer (see ‘LR’ of FIG. 8C) during the formation process of the shielding layer 140. For example, the first region 140R1, the second region 140R2, or the third region 140R3 may be regions in which the lifting of the adhesive layer is sequentially smaller. According to one or more embodiments, the shielding layer 140 may include a region in which the insertion portion 141 is not formed. For example, the insertion portion 141 may be formed at a corner in which the side surfaces 110S3 of the substrate 110 intersect, and the insertion portion 141 may not be formed in a region between the corners.

In the first region 140R1, the insertion portion 141 may extend to the outer surface 114OS of the insulation layer 114. The insertion portion 141 may extend into the open region OR to contact the barrier pattern 112BP and the outer surface 114OS of the insulation layer 114. The thickness of the insertion portion 141 in the vertical direction (the Z-direction) may decrease toward the outer surface 114OS of the insulation layer 114. The first region 140R1 may be understood as including the structure of the embodiment described above with reference to FIGS. 6A and 6B.

In the second region 140R2, the insertion portion 141 may extend to the barrier pattern 112BP. The insertion portion 141 may extend into the open region OR and come into contact with the barrier pattern 112BP. The thickness of the insertion portion 141 in the vertical direction (the Z-direction) may decrease toward the barrier pattern 112BP. The second region 140R2 may be understood as including the structure of the embodiment described above with reference to FIGS. 4A and 5C.

In the third region 140R3, the insertion portion 141 may extend into the open region OR but may be spaced apart from the barrier pattern 112BP. The thickness of the insertion portion 141 in the vertical direction (the Z-direction) may decrease toward the barrier pattern 112BP. The third region 140R3 may be understood as including the structure of the embodiment described above with reference to FIG. 1.

FIGS. 8A, 8B, 8C, 8D and 8E are diagrams illustrating a manufacturing process of a semiconductor package according to one or more embodiments.

Referring to FIG. 8A, a molding structure MS may be mounted on an adhesive layer 10. The molding structure MS may include a substrate strip 110’, semiconductor chips 120, a preliminary molding layer 130’, and connection bumps 115. The substrate strip 110’ may include a plurality of package substrates (e.g., PCBs) that are integrally connected. The semiconductor chips 120 may be mounted on the substrate strip 110’ in a flip-chip manner or a wire bonding manner. The substrate strip 110’ may include the barrier pattern 112BP and the insulation layer 114 corresponding to each unit substrate.

The adhesive layer 10 may be attached to a lower portion of the substrate strip 110’. The adhesive layer 10 may be formed to fill the open region OR and cover one or more, or all of the connection bumps 115. The adhesive layer 10 may include a thermosetting polymer or a photocurable polymer. In one or more embodiments, the adhesive layer 10 may include a thermosetting siloxane polymer or a photocurable silicone acryl polymer.

Referring to FIG. 8B, the unit packages 100 may be formed by cutting the molding structure MS and the adhesive layer 220 by a sawing process. The unit packages 100 to which the adhesive layer 10 is attached may be separated. The unit packages 100 may include the substrate 110 separated from the substrate strip 110’ and the molding layer 130 separated from the preliminary molding layer 130’.

Referring to FIG. 8C, the unit packages 100 may be attached on a base film 20. The unit packages 100 may be disposed so that the adhesive layer 10 faces the base film 20. The unit packages 100 may be disposed on the base film 20 in the horizontal direction by a pickup apparatus 30. A frame 21 may be attached to an end of the base film 20. The frame 21 may be formed of a metal material, but is not limited thereto. The base film 20 may be a film coated with an adhesive on at least one side. For example, the base film 20 may include a polyimide (PI) film, a polyethylene terephthalate (PET) film, or a polyethylene-naphthalate (PEN) film.

The lifted region LR of the adhesive layer 10 may occur at the edge of the substrate 110 due to warpage of the unit package 100, a decrease in the adhesive strength of the adhesive layer 10, peeling due to a sawing process, etc. According to one or more embodiments, the lifted region LR may extend to the outer surface 114OS of the barrier pattern 112BP or the insulation layer 114 (see FIGS. 4A-B, 5A-C, and 6A-B). The lifted region LR may cause backspill of a shielding material during a subsequent process and may reduce the productivity and reliability of the package. However, according to one or more embodiments, backspill of the shielding material may be suppressed, and short of the shielding layer 140 and the lower pad may be prevented.

Referring to FIG. 8D, a shielding material layer 140’ covering the unit packages 100 may be formed. The shielding material layer 140’ may cover at least a portion of each of the unit packages 100 and the adhesive layer 10. The shielding material layer 140’ may be conformally formed by a coating apparatus 40. The coating apparatus 40 may be deposition process equipment, such as a physical vapor deposition (PVD) apparatus and system or a chemical vapor deposition (CVD) apparatus and system. For example, the coating apparatus 40 may be a sputtering device, but may be not limited thereto.

The shielding material layer 140’ may be a thin film formed on the surface of each of the unit packages 100 and the adhesive layer 10. The shielding material layer 140’ may include at least one layer of a conductive thin film for EMI shielding. For example, the shielding material layer 140’ may be a three-layer thin film in which a stainless steel (SUS) film, a copper (Cu) film, and a SUS film are sequentially stacked.

According to one or more embodiments, the shielding material layer 140’ may be inserted into the lifted region LR of the adhesive layer 10. The barrier pattern 112BP and the outer surface 114OS of the insulation layer 114 sequentially arranged at the edge of the substrate 110 may suppress lifting of the adhesive layer 10 and prevent backspill of the shielding material layer 140’.

Referring to FIG. 8E, the unit packages 100 on which the electromagnetic shielding layer 140 is formed may be separated from the adhesive layer 10. The pickup apparatus 30 may pick up the unit packages 100 on which the shielding material layer 140’ may be formed. The interface between the unit packages 100 and the adhesive layer 10 may be separated by the pickup apparatus 30, and the shielding material layer 140’ may be cut to form the shielding layer 140 covering the unit packages 100. In this manner, the shielding layer 140 according to the embodiment may include the insertion portion 141 filling the lifted region LR of the adhesive layer 10.

According to one or more embodiments of the disclosure, a method of manufacturing a semiconductor package may include: separating unit packages to which an adhesive layer may be attached, wherein each of the unit packages includes a substrate, a semiconductor chip and a molding layer on the substrate, and an insulation layer below the substrate, wherein the substrate includes a lower pad facing the adhesive layer and a barrier pattern around the lower pad, and the insulation layer includes an open region exposing the barrier pattern; attaching the unit packages onto a base film; forming a shielding material layer covering the unit packages, wherein the shielding material layer is inserted into a lifted region between each of the unit packages and the adhesive layer, and the lifted region extends to the barrier pattern or an outer surface of the insulation layer; and separating the unit packages in which a shielding layer is formed from the adhesive layer, wherein the shielding layer includes an insertion portion filling the lifted region of the adhesive layer.

According to one or more embodiments of the disclosure, separating the unit packages may be performed by cutting the molding structure and the adhesive layer by a sawing process, and the unit packages may include the substrate separated from the substrate strip and the molding layer separated from the preliminary molding layer.

According to one or more embodiments of the disclosure, the shielding layer may be formed by conformally depositing a shielding material layer using a physical vapor deposition (PVD) process and/or a chemical vapor deposition (CVD) process.

According to one or more embodiments of the disclosure, the shielding material layer may be a three-layer thin film in which a stainless steel (SUS) film, a copper (Cu) film, and a SUS film are sequentially deposited to form a stack.

According to one or more embodiments of the disclosure, the barrier pattern and the outer surface of the solder resist layer may be sequentially arranged at the edge of the substrate and configured to suppress lifting of the adhesive layer and prevent backspill of the shielding material layer.

According to one or more embodiments of the disclosure, by limiting the backspill region of the shielding layer using the barrier pattern and the insulation layer, the semiconductor package with improved productivity and reliability may be provided.

The various advantageous and effective features and effects of the disclosure are not limited to the aforementioned contents and will be more easily understood in the course of describing specific embodiments of the disclosure.

While example embodiments have been shown and described above, it will be apparent to those skilled in the art that modifications and variations could be made without departing from the scope of the disclosure as defined by the appended claims.

What is claimed is:

1. A semiconductor package comprising:
a substrate comprising a first surface, a second surface opposing the first surface, one or more first pads on the first surface, one or more second pads on the second surface, and a barrier pattern around the one or more second pads along an edge of the second surface;
a semiconductor chip on the first surface and including one or more connection pads electrically connected to the one or more first pads;
a molding layer on the semiconductor chip on the first surface;
an insulation layer on at least a portion of each of the one or more second pads on the second surface and comprising an open region exposing at least a portion of the barrier pattern along the edge of the second surface; and
a shielding layer on at least a portion of the substrate and the molding layer, and comprising an insertion portion extending from the edge of the second surface to the open region,
wherein a thickness of the insertion portion decreases toward an outer surface of the insulation layer adjacent to the open region.

2. The semiconductor package of claim 1, wherein the outer surface of the insulation layer is between an outermost second pad of the one or more second pads and the barrier pattern.

3. The semiconductor package of claim 1, wherein the insulation layer has a thickness that is greater than a thickness of the barrier pattern in a direction perpendicular to the second surface.

4. The semiconductor package of claim 1, wherein the barrier pattern has a line width that is smaller than a width of the one or more second pads in a direction parallel to the second surface.

5. The semiconductor package of claim 1, wherein the shielding layer further comprises a shielding portion connected to the insertion portion, and
wherein the shielding portion comprises a first shielding portion on a side surface of the substrate and a side surface of the molding layer, and a second shielding portion on an upper surface of the molding layer.

6. The semiconductor package of claim 5, wherein a thickness of the first shielding portion and a thickness of the second shielding portion are greater than the thickness of the insertion portion.

7. The semiconductor package of claim 5, wherein the substrate further comprises a ground interconnection electrically connected to at least a portion of each of the one or more first pads and the one or more second pads, and
wherein the shielding layer is connected to the ground interconnection through the first shielding portion.

8. The semiconductor package of claim 1, wherein a width of the open region in a direction perpendicular to the outer surface of the insulation layer is at least 100 μm.

9. The semiconductor package of claim 1, wherein a gap between the barrier pattern and the edge of the second surface in a direction perpendicular to the outer surface of the insulation layer is at least 10 μm.

10. The semiconductor package of claim 1, wherein the open region comprises a plurality of open regions spaced apart from each other along the edge of the second surface.

11. The semiconductor package of claim 10, wherein the insulation layer comprises first outer surfaces adjacent to an inner end of the plurality of open regions, and second outer surfaces adjacent to the edge of the second surface, and the insertion portion of the shielding layer extends toward the first outer surfaces.

12. The semiconductor package of claim 1, wherein the barrier pattern has a thickness that is greater than a thickness of the one or more second pads in a direction perpendicular to the second surface.

13. The semiconductor package of claim 1, wherein the insertion portion contacts at least one of at least a portion of the barrier pattern or the outer surface of the insulation layer.

14. The semiconductor package of claim 13, wherein the substrate further comprises a ground interconnection electrically connected to at least one of the one or more first pads and the one or more second pads, and
wherein the barrier pattern is connected to the ground interconnection or a ground pad connected to the ground interconnection among the one or more second pads.

15. The semiconductor package of claim 14, wherein the substrate further comprises a ground pattern connected to the barrier pattern and the ground pad.

16. The semiconductor package of claim 14, wherein the substrate further comprises a ground via connected to the barrier pattern and the ground interconnection.

17. A semiconductor package comprising:
a substrate comprising a first surface, a second surface opposing the first surface, one or more first pads on the first surface, one or more second pads on the second surface, and a barrier pattern around the one or more second pads;
a semiconductor chip on the first surface and comprising one or more connection pads electrically connected to the one or more first pads;
a molding layer on the semiconductor chip on the first surface;
an insulation layer on the second surface and comprising an outer surface spaced apart from the barrier pattern;
one or more connection bumps on the one or more second pads; and
a shielding layer comprising a shielding portion on at least a portion of the substrate and the molding layer, and an insertion portion extending from one end of the shielding portion toward the outer surface of the insulation layer.

18. The semiconductor package of claim 17, wherein the barrier pattern is around the outer surface of the insulation layer.

19. A semiconductor package comprising:
a substrate comprising a ground interconnection, a lower pad electrically connected to the ground interconnection, and a barrier pattern on at least one side of the lower pad;
a semiconductor chip on the substrate and electrically connected to the ground interconnection;
a molding layer on the semiconductor chip;
an insulation layer comprising an opening exposing the lower pad, and an open region exposing at least a portion of the barrier pattern;
a connection bump on the lower pad; and
a shielding layer comprising a shielding portion on at least a portion of the substrate and the molding layer, and an insertion portion extending from one end of the shielding portion to the open region,
wherein the barrier pattern is electrically connected to the ground interconnection or the lower pad, and
wherein the insertion portion is in contact with the barrier pattern.

20. The semiconductor package of claim 19, wherein a thickness of the insertion portion decreases toward an inside of the open region.
